(19) United States
(12) Patent Application Publication
(10) Pub. No.: US 2021/0098358 A1
(43) Pub. Date: Apr. 1, 2021

(54) SEMICONDUCTOR PACKAGE

(71) Applicant: CHANG WAH TECHNOLOGY CO., LTD., Kaohsiung City (TW)

(72) Inventor: Chia-Neng HUANG, Kaohsiung City (TW)

(21) Appl. No.: 16/719,180

(22) Filed: Dec. 18, 2019

(30) Foreign Application Priority Data
Sep. 27, 2019 (TW) 108212872

(51) Int. Cl. H01L 23/498; H01L 23/31; H01L 23/00

(52) U.S. Cl. CPC H01L 23/49838; H01L 23/49861; H01L 24/45; H01L 23/49811; H01L 23/3114

(57) ABSTRACT

A semiconductor package includes a lead frame, a chip unit, and an encapsulation layer. The lead frame includes a die pad and a plurality of package leads. Each of the package leads has a proximate segment and a distal segment relative to the die pad. Each of the package leads has an outer end surface which. interconnects bottom and top surface regions of the distal segment, and a cavity which is formed the bottom surface region of the distal segment, and which extends inwardly from the outer end surface. The chip unit includes a chip and a plurality of wire bonds. The encapsulation layer encapsulates the lead frame and the chip unit such that the distal segment of each of the package leads is exposed from the encapsulation layer.

### CROSS-REFERENCE TO RELATED APPLICATION

This application claims priority of Taiwanese Utility Model Patent Application No. 108212872, filed on Sep. 27, 2019.

### FIELD

This disclosure relates to a semiconductor package, and more particularly to a semiconductor package having a plurality of package leads each of which is formed with a cavity.

### BACKGROUND

As shown in FIG. 1, a conventional semiconductor package includes a lead frame 11, an encapsulation layer 12, and a chip (not shown) disposed on the lead frame 11 and encapsulated by the encapsulation layer 12. The lead frame 11 includes a die pad 111 for mounting the chip, and a plurality leads 112 which are spaced apart from and displaced around the die pad 111. The leads 112 are exposed from the encapsulation layer 12.

Each of the leads 112 has a flat bottom surface 113, and, therefore, when the semiconductor package is soldered to a circuit board, a melted solder is unlikely to flow from the flat bottom surface 113 to a side surface of each of the leads 112 during a reflow soldering procedure. The bonding strength between the semiconductor package and the circuit board largely depends on the contact area between the solder and the leads 112. Further, if the solder cannot be seen from the side surface of the leads 112, it is impossible to visually check the contact condition between the solder and the leads 112, which may increase the difficulty of quality control.

### SUMMARY

Therefore, an object of the disclosure is to provide a semiconductor package that can alleviate at least one of the drawbacks of the prior art.

According to the disclosure, a semiconductor package includes a lead frame, a chip unit, and an encapsulation layer. The lead frame includes a die pad and a plurality of package leads which are spaced apart from and angularly displaced around the die pad. Each of the package leads has a proximate segment and a distal segment relative to the die pad. Each of the package leads has an outer end surface which interconnects a bottom surface region and a top surface region of the distal segment. Each of the package leads has a cavity which is formed in the bottom surface region of the distal segment, and which extends inwardly from the outer end surface. The chip unit includes a chip which is disposed on the die pad, and a plurality of wire bonds each of which is disposed to electrically couple the chip to a respective one of the package leads. The encapsulation layer is disposed to encapsulate the lead frame and the chip unit such that the distal segment of each of the package leads is exposed from the encapsulation layer, and such that the die pad, the package leads, and the encapsulation layer are flush with each other at their bottoms.

### BRIEF DESCRIPTION OF THE DRAWINGS

Other features and advantages of the disclosure will become apparent in the following detailed description of the embodiment with reference to the accompanying drawings, in which:

FIG. 1 is a perspective bottom view of a conventional semiconductor package;

FIG. 2 is a perspective bottom view of an embodiment of a semiconductor package according to the disclosure;

FIG. 3 is a perspective top view of the embodiment of the semiconductor package according to the disclosure;

FIG. 4 is a cross-sectional view of the embodiment taken along line 4-4 of FIG. 3; and

FIGS. 5 and 6 are perspective views illustrating consecutive steps for producing the embodiment of the semiconductor package.

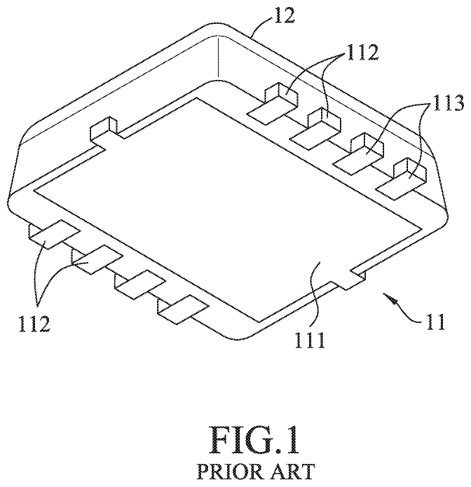

### DETAILED DESCRIPTION

Before the disclosure is described in greater detail, it should be noted that where considered appropriate, reference numerals have been repeated among the figures to indicate corresponding or analogous elements, which may optionally have similar characteristics.

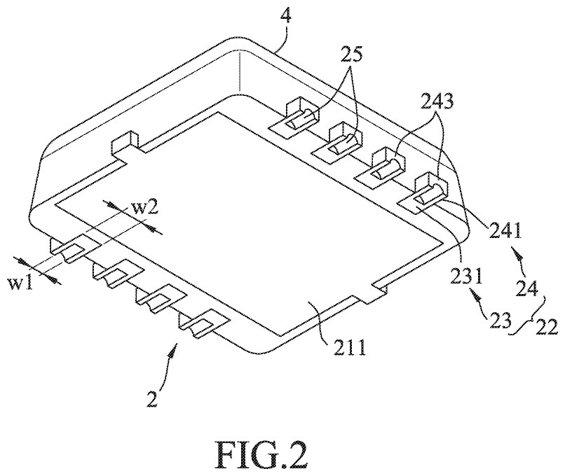

As shown in FIGS. 2 to 4, an embodiment of a semiconductor package according to this disclosure includes a lead frame 2, a chip unit 3, and an encapsulation layer 4.

The lead frame 2 includes a die pad 21, and a plurality of separated package leads 22 which are spaced apart from and angularly displaced around the die pad 21.

The die pad 21 has a bottom surface 211 and a top surface 212 opposite to the bottom surface 211, and is made of an electrically conductive material such as a copper alloy or an iron-nickel alloy, but is not limited thereto.

Each of the package leads 22 is made of an electrically conductive material (e.g., the same material as that of the die pad 21), and has a proximate segment 23 and a distal segment 24 relative to the die pad 21. Each of the package leads 22 has a bottom surface 221 which is composed of a bottom surface region 231 of the proximate segment 23 and a bottom surface region 241 of the distal segment 24. Similarly, each of the package leads 22 further has a top surface 222 which is composed of a top surface region 232 of the proximate segment 23 and a top surface region 242 of the distal segment 24. Each of the package leads 22 further has an outer end surface 243 which interconnects the bottom surface region 241 and the top surface region 242 of the distal segment 24. The outer end surface 243 of each of the package leads 22 is a surface farthest away from the die pad 21.

In addition, each of the package leads 22 has a cavity 25 which is formed in the bottom surface region 241 of the distal segment 24, and which extends inwardly from the outer end surface 243. It should be noted that, the cavity 25 may be in any shape. For example, the cavity 25 may be a semi-cylinder with a uniform width, or a irregular or asymmetrical configuration without a uniform width, but is not limited thereto in this embodiment, the cavity 25 of each of the package leads 22 is a semi-cylinder with a uniform width (w1).

The chip unit 3 includes a chip 31 which is disposed on the top surface 212 of the die pad 21, and a plurality of wire bonds 32 each of which is disposed to electrically couple the chip 31 to a respective one of the package leads 22.

The encapsulation layer 4 is disposed to encapsulate the lead frame 2 and the chip unit 3 such that the distal segment 24 of each of the package leads 22 is exposed from the encapsulation layer 4, and such that the die pad 21, the package leads 22, and the encapsulation layer 4 are flush with each other at their bottoms. That is, the bottom surface 211 of the die pad 21, and the bottom surface regions 231, 241 of the proximate segment 23 and the distal segment 24 are exposed from the encapsulation layer 4 and coplanar with a lower major surface 41 of the encapsulation layer 4. It should be noted that, the encapsulation layer 4 does not fill be cavities 25 of the package leads 22. To be specific, the encapsulation layer 4 is not disposed in the cavities 25. The encapsulation layer 4 may be made of a transparent or non-transparent electrically insulating material, but is not limited thereto. In this embodiment, the encapsulation layer 4 is made of a non-transparent electrically insulating material.

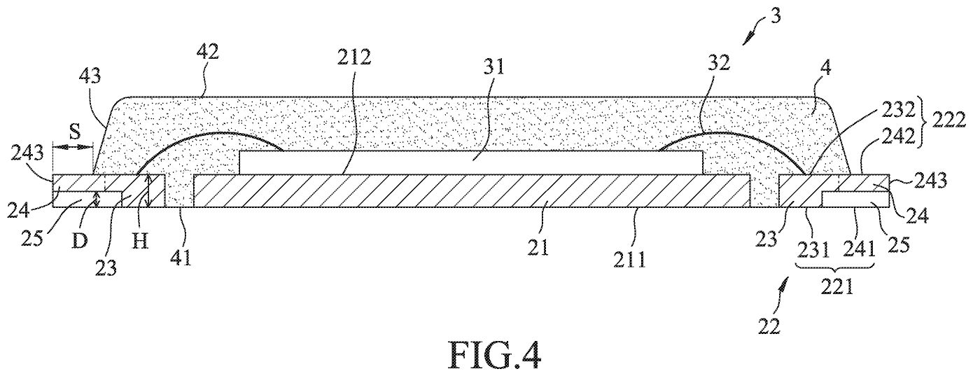

In an embodiment, the cavity 25 is formed in the bottom of each of the package leads 22, and the encapsulation layer 4 covers a part of the distal segment 24 such that an orthographic projection of a contour of the cavity 25 overlaps with an orthographic projection of the encapsulation layer 4 (see FIG. 4).

In an embodiment, the cavity 25 of each of the package leads 22 extends inwardly from the outer end surface 243 of the distal segment 24 into the proximate segment 23 so as to permit a greater contact area between the semiconductor package of this disclosure and a solder material to be used in a subsequent procedure. In this case, the orthographic projection of the contour of the cavity 25 overlaps with the orthographic projection of the encapsulation layer 4 whether or not the encapsulation layer 4 covers the distal segment 24.

In an embodiment, a minimum distance (S) from the outer end surface 243 of the distal segment 24 of each of the package leads 22 to a periphery of the encapsulation layer 4 ranges from 0.05 mm to 0.3 mm (see FIG. 4). As such, a size of the semiconductor package can be kept within a more desirable range.

In order to maintain the strength of the package leads 22, for each of the package leads 22, the width (w1) of the cavity 25 is designed to be smaller than a width (w2) of the package lead 22, and a depth (D) of the cavity 25 is designed to be smaller than a height (H) of the package lead 22 between the bottom and top surfaces 221, 222 (see. FIGS. 2 and 4).

As shown FIG. 4, an embodiment, the encapsulation layer 4 has an upper major surface 42 opposite to the lower major surface 41, and a minor surrounding surface 43 interconnecting the upper and lower major surfaces 42, 41. The top surface region 242 of the distal segment 24 has an exposed area which is exposed from the encapsulation layer 4. The exposed area defines an obtuse angle together with the minor surrounding surface 43 of the encapsulation layer 4.

As shown in FIGS. 2 to 4, in an embodiment, each of the upper and lower major surfaces 42, 41 of the encapsulation layer 4 is in a quadrilateral shape with rounded corners. Cross-sections of the encapsulation layer 4, which are taken parallel to the upper major surface 42, are gradually increased in dimension from the upper major surface 42 to the lower major surface 41.

In certain embodiments, an electrically conductive coating layer (not shown) may be further disposed between the lead frame 2 and the encapsulation layer 4 to increase an adhesion strength therebetween. The electrically conductive coating layer may be made from metals (e.g., nickel, palladium, silver, gold, etc.) or alloys. The electrically conductive coating layer may further increase the adhesion strength between the lead frame 2 and the wire bonds 32, so as to improve the reliability and performance of the semiconductor package. In addition, the electrically conductive coating layer may increase the wettability of the solder material on the package leads 22 so as to permit the solder material to easily climb up from the bottom surface 221 to the outer end surface 243 of each of the package leads 22 through the cavity 25. As such, a contact area between the semiconductor package and the solder material may be greatly increased, and the soldering condition may become visually observable from the outer end surface 243 of each of the package leads 22.

A method for producing the semiconductor package of the disclosure is illustrated as follows.

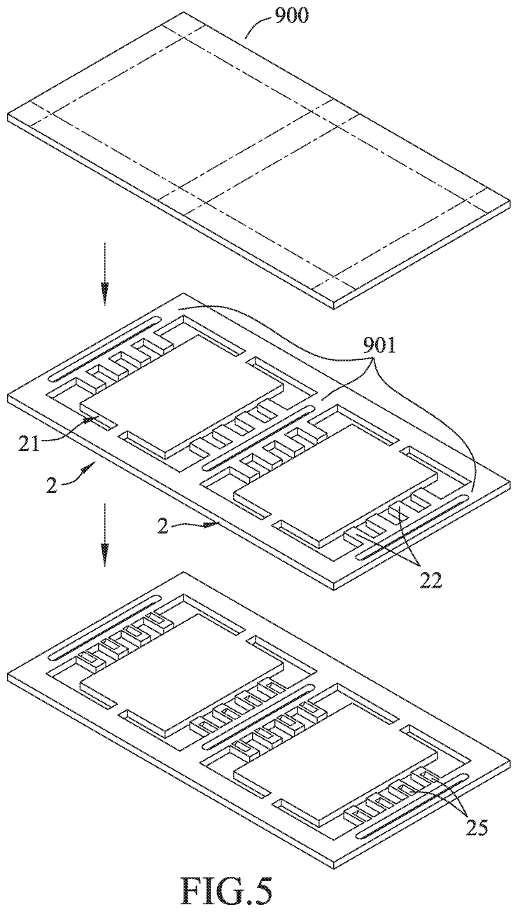

As shown in FIG. 5, an electrically conductive substrate 900 (e.g., a copper alloy substrate or an iron-nickel alloy substrate) is provided. Then, the substrate 900 is subjected to a first etching procedure to remove unnecessary portions of the substrate 900 so as to form a plurality of lead frames 2 (two of the lead frames 2 are exemplified in FIG. 5) and a plurality of connecting portions 901 interconnecting the adjacent two of the lead frames 2. Each of the lead frames 2 includes the die pad 21, and a plurality of the separated package leads 22 which are spaced apart from one another and extend from the connecting portions 901 toward the die pad 21. The package leads 22 are spaced apart from and angularly displaced around the die pad 21.

After the first etching step, a second etching step is performed on the package leads 22 so as to form the cavities 25 in the package leads 22. In particular, each of the package leads 22 is etched from the bottom surface 221 toward the top surface 222 to form the cavity 25 which extends in a direction from a respective one of the connecting portions 901 toward the die pad 21.

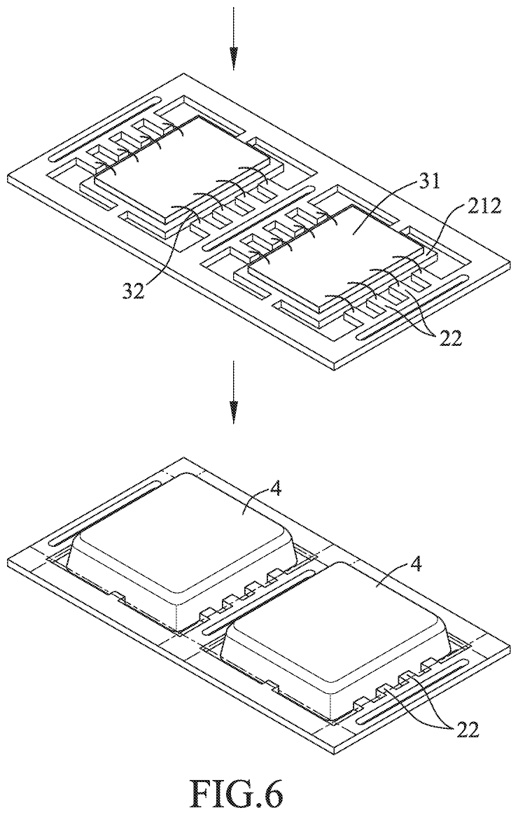

As shown in FIG. 6, after the second etching step, the chips 31 are respectively provided on the top surfaces 212 of the die pads 21. Then, a plurality of the wire bonds 32 are formed by the wire bonding process, and electrically couples the package leads 22 to the corresponding chips 31 so as to obtain a semi-finished product.

Subsequently, the semi-finished product is placed in a mold (not shown) and an encapsulant is injected into the mold. The encapsulant is then solidified to form the encapsulation layers 4 each of which encapsulates a respective one of the lead frame 2 and a respective one of the chip units 3 such that the distal segment 24 of a respective one of the package leads 22 and a respective one of the cavities 25 are exposed from the encapsulation layer 4. Thus, an encapsulated semi-finished product is obtained.

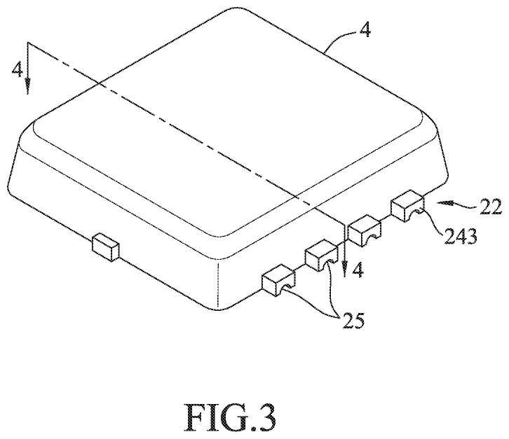

Finally, the encapsulated semi-finished product is diced along scribe lines (as shown by the phantom lines in FIG. 6) to obtain two separated semiconductor packages as illustrated in FIGS. 2 and 3.

In sum, with the cavity 25 formed at the bottom of each of the package leads 22 and extending inwardly from the outer end surface 243, it may be easier for the solder material to climb up from the bottom surface 221 to the outer end surface 243. As such, the contact area between the solder material and the package leads 22 may be greatly increased, and the soldering condition may be visually observable from the outer end surface 243 of each of the package leads 22.

In the description above, for the purpose of explanation, numerous specific details have been set forth in order to provide a thorough understanding of the embodiment. It will be apparent, however, to one skilled in the art, that one or more other embodiments may be practiced without some of these specific details It should also be appreciated that reference throughout this specification “one embodiment,” “an embodiment,” an embodiment with an indication of an ordinal number and so forth means that a particular feature, structure, or characteristic may be included. in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what s considered the exemplary embodiments, it is understood that this disclosure is not limited to the disclosed embodiments but is intended. to cover various arrangements included within the spirit and scope of the broadest interpretation so as to encompass all such modifications and equivalent arrangements.

What is claimed is:

1. A semiconductor package, comprising:
a lead frame including a die pad, and a plurality of package leads which are spaced apart from and angularly displaced around said die pad, each of said package leads having a proximate segment and a distal segment relative to said die pad, each of said package leads having an outer end surface which interconnects a bottom surface region and a top surface region of said distal segment, each of said package leads having a cavity which is formed in said bottom surface region of said distal segment, and which extends inwardly from said outer end surface;
a chip unit including a chip which is disposed on said die pad, and a plurality of wire bonds each of which is disposed to electrically couple said chip to a respective one of said package leads; and
an encapsulation layer disposed to encapsulate said lead frame and said chip unit such that said distal segment of each of said package leads is exposed from said encapsulation layer, and such that said die pad, said package leads, and said encapsulation layer are flush with each other at their bottoms.

2. The semiconductor package according to claim 1, wherein said cavity is formed in the bottom of each of said package leads such that an orthographic projection of a contour of said cavity overlaps with an orthographic projection of said encapsulation layer.

3. The semiconductor package according to claim 2, wherein said cavity of each of said package leads extends inwardly from said outer end surface of said. distal segment into said proximate segment.

4. The semiconductor package according to claim 1, wherein for each of said package leads, a width of said cavity is smaller than a width of said package lead, and a depth of said cavity is smaller than a height of said package lead between said top surface region and said bottom surface region of said distal segment.

5. The semiconductor package according to claim 1, wherein a minimum distance from said outer end surface of said distal segment of each of said package leads to a periphery of said encapsulation layer ranges from 0.05 mm to 0.3 mm.

6. The semiconductor package according to claim 1, wherein said encapsulation layer has an upper major surface, a lower major surface, and a minor surrounding surface interconnecting said upper and lower major surfaces, said top surface region of said distal segment having an exposed area, which is exposed from said encapsulation layer, and which defines an obtuse angle together with said minor surrounding surface.

7. The semiconductor package according to claim 6, wherein each of said upper and lower major surfaces of said encapsulation layer is in a quadrilateral shape with rounded corners, cross-sections of said encapsulation layer, which are taken parallel to said upper major surface, being gradually increased in dimension from said upper major surface to said lower major surface.
